(19) United States
(12) Patent Application Publication
(10) Pub. No.: US 2025/0107343 A1
(43) Pub. Date: Mar. 27, 2025

(54) DISPLAY DEVICE AND METHOD OF MANUFACTURING DISPLAY DEVICE

(71) Applicant: Samsung Display Co., LTD., Yongin-si (KR)

(72) Inventors: Hyun Eok SHIN, Yongin-si (KR); Joon Yong PARK, Yongin-si (KR); Dong Min LEE, Yongin-si (KR); Yung Bin CHUNG, Yongin-si (KR)

(73) Assignee: Samsung Display Co., LTD., Yongin-si (KR)

(21) Appl. No.: 18/745,412

(22) Filed: Jun. 17, 2024

(30) Foreign Application Priority Data
Sep. 25, 2023 (KR) 10-2023-0128607

(51) Int. Cl. H10K 59/122; H10K 59/12; H10K 59/80; H10K 71/60; H10K 102/00; H10K 102/10

(52) U.S. Cl. CPC H10K 59/122; H10K 59/1201; H10K 59/80522; H10K 71/60; H10K 2102/103; H10K 2102/351

(57) ABSTRACT

A display device may include a light emitting portion disposed on a base layer; a partition wall disposed adjacent to the light emitting portion; and a partition wall insulating layer covering at least a portion of the partition wall. The partition wall may include a first partition wall layer; a second partition wall layer disposed on the first partition wall layer; and a third partition wall layer disposed on the second partition wall layer. The third partition wall layer may include a Transparent Conductive Oxide (TCO) material, and the partition wall insulating layer may not cover a top surface of the light emitting portion.

### CROSS-REFERENCE TO RELATED APPLICATION

The application claims priority under 35 U.S.C. § 119(a) to Korean patent application No. 10-2023-0128607 filed on Sep. 25, 2023 in the Korean Intellectual Property Office (KIPO), the entire disclosure of which is incorporated herein by reference.

### BACKGROUND

### 1. Technical Field

The disclosure generally relates to a display device and a method of manufacturing a display device.

### 2. Description of the Related Art

With the development of information technologies, the importance of a display device which is a connection medium between a user and information increases. Particularly, as demands for high-quality display devices increase, discussion on display devices including a light emitting element having a micro scale or nano scale size has been actively made.

A display device may include a partition wall defining an area in which a light emitting portion is disposed. In a display device including a light emitting element having a micro scale or nano scale size, a distance between partition walls may be narrowed to the micro scale or nano scale size. As the distance between the partition walls is narrowed, a risk that a leakage current may be generated between the partition walls may increase.

### SUMMARY

Embodiments provide a display device and a method of manufacturing a display device, which can increase light emission efficiency and reduce a risk that a leakage current may be generated between partition walls.

The technical objectives to be achieved by the disclosure are not limited to those described herein, and other technical objectives that are not mentioned herein would be clearly understood by a person skilled in the art from the description of the disclosure.

In accordance with an aspect of the disclosure, there is provided a display device including a light emitting portion disposed on a base layer; a partition wall disposed adjacent to the light emitting portion; and a partition wall insulating layer covering at least a portion of the partition wall, wherein the partition wall includes a first partition wall layer; a second partition wall layer disposed on the first partition wall layer; and a third partition wall layer disposed on the second partition wall layer, wherein the third partition wall layer includes a Transparent Conductive Oxide (TCO) material, and wherein the partition wall insulating layer does not cover a top surface of the light emitting portion.

The first partition wall layer and the third partition wall layer may protrude outwardly of the second partition wall layer in a direction in which a plane on which the base layer is disposed extends.

The second partition wall layer may include a reflective metal material, and the first partition wall layer may include a TCO material.

The first partition wall layer may include at least one selected from the group consisting of Indium Tin Oxide (ITO), Indium Zinc Oxide (IZO), Indium Gallium Zinc Oxide (IGZO), and Aluminum Zinc Oxide (AZO), the second partition wall layer may include at least one of silver (Ag) and aluminum (Al), and the third partition wall layer may include an amorphous TCO material.

The first partition wall layer may have a thickness in a range of about 30 Å to about 100 Å, the second partition wall layer may have a thickness in a range of about 4000 Å to about 10000 Å, and the third partition wall layer may have a thickness in a range of about 500 Å to about 2000 Å.

The partition wall insulating layer may cover a side surface of each of the first partition wall layer, the second partition wall layer, and the third partition wall layer.

The partition wall insulating layer may be in contact with at least a portion of a side surface of the light emitting portion. The first partition wall layer may be in contact with the second partition wall layer, and the third partition wall layer may be in contact with the second partition wall layer.

The partition wall insulating layer may not cover a top surface of the third partition wall layer.

The partition wall insulating layer may include at least one selected from the group consisting of silica (SiO₂) and aluminum oxide (Al₂O₃).

The partition wall insulating layer may have a thickness in a range of about 100 Å to about 500 Å.

The display device may further include a second electrode disposed on the light emitting portion; and an auxiliary electrode disposed on the second electrode, the auxiliary electrode being electrically connected to the second electrode.

The auxiliary electrode may include at least one selected from the group consisting of a TCO material and titanium nitride (TIN).

In accordance with another aspect of the disclosure, there is provided a method of manufacturing a display device, the method including forming a first electrode on a base layer; forming a partition wall on the base layer; forming a partition wall insulating layer on the partition wall; forming a light emitting portion adjacent to the partition wall; forming a second electrode on the light emitting portion; and forming an auxiliary electrode on the second electrode, wherein the forming of the partition wall on the base layer includes depositing a first base partition wall layer; depositing a second base partition wall layer on the first base partition wall layer; and depositing a third base partition wall layer on the second base partition wall layer, wherein the third base partition wall layer includes a Transparent Conductive Oxide (TCO) material, and wherein the forming of the auxiliary electrode on the second electrode includes disposing the auxiliary electrode directly on the second electrode such that the auxiliary electrode and the second electrode are electrically connected to each other.

The method may further include forming a base pixel defining layer to cover the first electrode. The first base partition wall layer may be deposited on the base pixel defining layer. The forming of the partition wall on the base layer may include forming a first partition wall layer, a second middle partition wall layer, and a third partition wall layer by collectively performing wet etching on the first base partition wall layer, the second base partition wall layer, and the third base partition wall layer; and forming a second partition wall layer having a structure retracted inwardly of the first partition wall layer and the third partition wall layer by further etching the second middle partition wall layer.

The third partition wall layer may include at least one selected from the group consisting of Indium Zinc Oxide (IZO) and Indium Gallium Zinc Oxide (IGZO).

The forming of the partition wall insulating layer on the partition wall may include depositing a base partition wall insulating layer to cover a side surface of the partition wall, a top surface of the third partition wall layer, and at least a portion of a top surface of the base pixel defining layer; and exposing the top surface of the third partition wall layer by performing dry etching on the base partition wall insulating layer.

The method may further include forming a pixel defining layer on the partition wall. The forming of the pixel defining layer may include removing at least a portion of the base pixel defining layer; and exposing, by the pixel defining layer, at least a portion of the first electrode. The removing and the forming of the partition wall insulating layer may be performed in the same dry etching process.

The base partition wall insulating layer may include silica (SiO₂) or aluminum oxide (Al₂O₃). In case that the base partition wall insulating layer includes the silica (SiO₂), the base partition wall insulating layer may be deposited through a Chemical Vapor Deposition (CVD) process. In case that the base partition wall insulating layer includes the aluminum oxide (Al₂O₃), the base partition wall insulating layer may be deposited through an Atomic Layer Deposition (ALD) process.

The forming of the auxiliary electrode on the second electrode may include depositing the auxiliary electrode through an ALD process. The auxiliary electrode may include at least one selected from the group consisting of a TCO material and titanium oxide (TiN).

In accordance with still another aspect of the disclosure, there is provided a display device including a first electrode disposed on a base layer; a light emitting portion disposed on the first electrode; a second electrode disposed on the light emitting portion; a partition wall disposed adjacent to the light emitting portion; a partition wall insulating layer covering at least a portion of the partition wall; and an auxiliary electrode covering the second electrode and the partition wall, wherein the partition wall includes a first partition wall layer; a second partition wall layer disposed on the first partition wall layer; and a third partition wall layer disposed on the second partition wall layer, wherein the third partition wall layer includes an amorphous Transparent Conductive Oxide (TCO) material, wherein the partition wall insulating layer include an inorganic material, and wherein the second electrode and the auxiliary electrode are electrically connected to each other.

### BRIEF DESCRIPTION OF THE DRAWINGS

FIG. 1 is a schematic plan view illustrating a display device in accordance with an embodiment of the disclosure.

FIG. 2 is a schematic sectional view illustrating a display device in accordance with an embodiment of the disclosure.

FIG. 3 is a sectional view illustrating an embodiment of a light emitting element shown in FIG. 2.

FIG. 4 is a sectional view illustrating another embodiment of the light emitting element shown in FIG. 2.

FIG. 5 is a schematic block diagram illustrating an electrical connection structure of a light emitting element in accordance with an embodiment of the disclosure.

FIG. 6 is a schematic flowchart illustrating a method of manufacturing the display device in accordance with an embodiment of the disclosure.

FIGS. 7 to 14 are schematic sectional views illustrating process steps of the method of manufacturing the display device in accordance with an embodiment of the disclosure.

FIG. 15 is a schematic block diagram of a display system in accordance with an embodiment of the disclosure.

FIG. 16 is a schematic perspective view illustrating an application example of the display system shown in FIG. 15.

### DETAILED DESCRIPTION OF THE EMBODIMENTS

The disclosure may apply various changes and different shape, therefore only illustrate in detail with particular examples. However, the examples do not limit to certain shapes but apply to all the change and equivalent material and replacement. The drawings included are illustrated a fashion where the figures are expanded for the better understanding.

It will be understood that, although the terms “first,” “second,” etc. may be used herein to describe various elements, these elements should not be limited by these terms. These terms are only used to distinguish one element from another element. Thus, a “first” element discussed below could also be termed a “second” element without departing from the teachings of the disclosure. As used herein, the singular forms are intended to include the plural forms as well, unless the context clearly indicates otherwise.

It will be further understood that the terms “includes” and/or “including,” when used in this specification, specify the presence of stated features, integers, steps, operations, elements, and/or components, but do not preclude the presence and/or addition of one or more other features, integers, steps, operations, elements, components, and/or groups thereof. Further, an expression that an element such as a layer, region, substrate or plate is placed “on” or “above” another element indicates not only a case where the element is placed “directly on” or “just above” the other element but also a case where a further element is interposed between the element and the other element. On the contrary, an expression that an element such as a layer, region, substrate or plate is placed “beneath” or “below” another element indicates not only a case where the element is placed “directly beneath” or “just below” the other element but also a case where a further element is interposed between the element and the other element.

As customary in the field, some embodiments are described and illustrated in the accompanying drawings in terms of functional blocks, units, parts, and/or modules. Those skilled in the art will appreciate that these blocks, units, parts, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, parts, and/or modules being implemented by microprocessors or other similar hardware, they may be programmed and controlled using software (e.g., microcode) to perform various functions discussed herein and may optionally be driven by firmware and/or software. It is also contemplated that each block, unit, part, and/or module may be implemented by dedicated hardware, or as a combination of dedicated hardware to perform some functions and a processor (e.g., one or more programmed microprocessors and associated circuitry) to perform other functions. Also, each block, unit, part, and/or module of some embodiments may be physically separated into two or more interacting and discrete blocks, units, parts, and/or modules without departing from the scope of the disclosure. Further, the blocks, units, parts, and/or modules of some embodiments may be physically combined into more complex blocks, units, parts, and/or modules without departing from the scope of the disclosure.

The term “and/or” includes all combinations of one or more of which associated configurations may define. For example, “A and/or B” may be understood to mean “A, B, or A and B.”

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

The term “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

The disclosure relates to a display device and a method of manufacturing a display device. Hereinafter, a display device and a method of manufacturing a display device in accordance with an embodiment of the disclosure will be described with reference to the accompanying drawings.

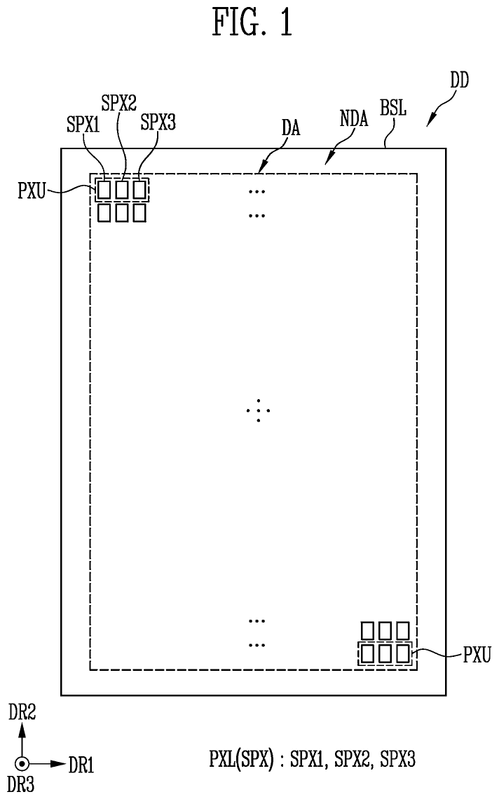

FIG. 1 is a schematic plan view illustrating a display device in accordance with an embodiment of the disclosure.

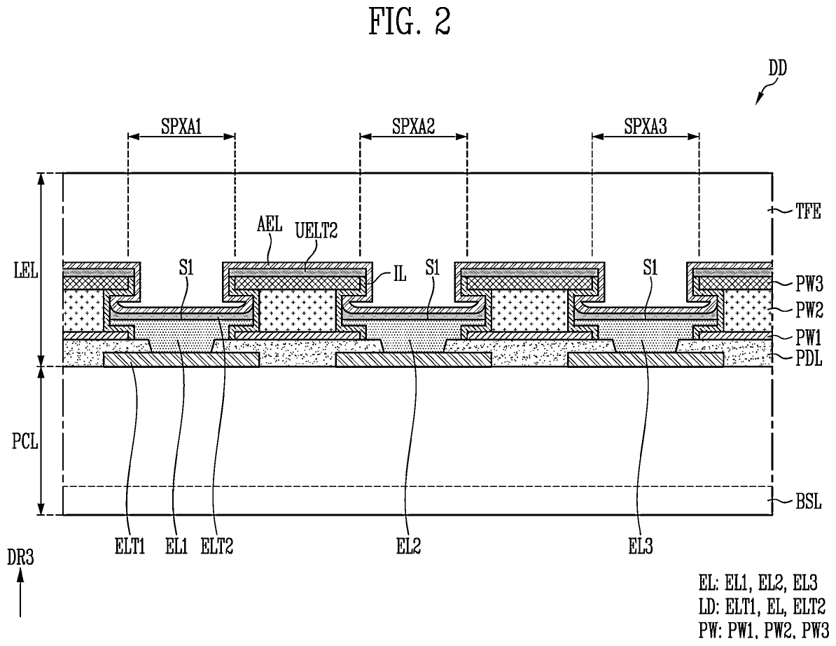

Referring to FIG. 1, the display device DD may be configured to emit light. The display device DD may include a light emitting element LD (see FIG. 2). In some embodiments, the display device DD may be a device which displays moving images or still images. The display device DD may be used as a display screen of not only portable electronic devices such as a mobile phone, a smart phone, a tablet personal computer (PC), a smart watch, a watch phone, a mobile communication terminal, an electronic notebook, an e-book reader, a portable multimedia player (PMP), a navigation system, and an ultra-mobile personal computer (UMPC), but also various products such as a television, a laptop computer, a monitor, an advertisement board, and an Internet of things (IoT) device. However, the application field of the display device DD is not limited to a specific example.

The display device DD may be formed in a rectangular plane having short sides in a first direction DR1 and long sides in a second direction DR2 intersecting the first direction DR1. A corner at which the short side in the first direction DR1 and the long side in the second direction DR2 meet each other may be formed round to have a curvature (e.g., a predetermined or selectable curvature) or be formed at a right angle. The planar shape of the display device DD is not limited to a quadrangular shape as shown or a particular shape, and the display device DD may be formed in a round shape such as another polygonal shape, a circular shape, or an elliptical shape. The display device DD may be formed flat, but the disclosure is not limited thereto. For example, the display device DD may include a curved portion which is formed at a left or right end and has a constant curvature or a changing curvature. In addition, the display device DD may be formed flexible enough to be warpable, curvable, bendable, foldable or rollable.

In the disclosure, the first direction DR1 may be a “horizontal” direction as a row direction of pixels PXL. The second direction DR2 may be a column direction of pixels PXL. A third direction DR3 may be a display direction of the display device DD or a normal direction of a plane on which a base layer BSL is disposed.

The display device DD may include a display area DA and a non-display area NDA. The non-display area NDA may be an area except the display area DA. The non-display area NDA may surround at least a portion of the display area DA.

The display area DA may be an area in which pixels PXL are disposed. The non-display area NDA may be an area in which the pixels PXL are not disposed. A driving circuit, lines, and pads, which are electrically connected to the pixels PXL of the display area DA, may be disposed in the non-display area NDA.

In some embodiments, each pixel PXL (or sub-pixels SPX) may include a first sub-pixel SPX1, a second sub-pixel SPX2, and a third sub-pixel SPX3. At least one first sub-pixel SPX1, at least one second sub-pixel SPX2, and at least one third sub-pixel SPX3 may constitute a pixel unit PXU capable of emitting lights of various colors. In FIG. 1, it is illustrated that each pixel PXL includes three sub-pixels SPX1, SPX2, and SPX3, e.g., a first sub-pixel SPX1, a second sub-pixel SPX2, and a third sub-pixel SPX3. However, the embodiment of the disclosure is not limited thereto.

In some embodiments, the pixels PXL (or sub-pixels SPX) may be arranged according to a stripe arrangement structure, a PENTILET arrangement structure, or the like. However, the disclosure is not limited thereto.

The first sub-pixel SPX1 may emit first light, the second sub-pixel SPX2 may emit second light, and the third sub-pixel SPX3 may emit third light. The first light may be light in a red wavelength band, the second light may be light in a green wavelength band, and the third light may be light in a blue wavelength band. The red wavelength band may be a wavelength band of about 600 nm to about 750 nm, the green wavelength band may be a wavelength band of about 480 nm to about 560 nm, and the blue wavelength band may be a wavelength band of about 370 nm to about 460 nm. However, the embodiment of the disclosure is not limited thereto.

Each of the first sub-pixel SPX1, the second sub-pixel SPX2, and the third sub-pixel SPX3 may include an Organic Light Emitting Diode (OLED) emitting light.

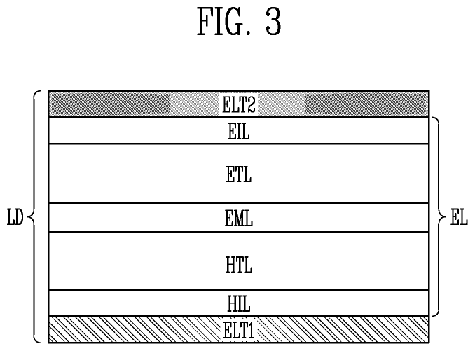

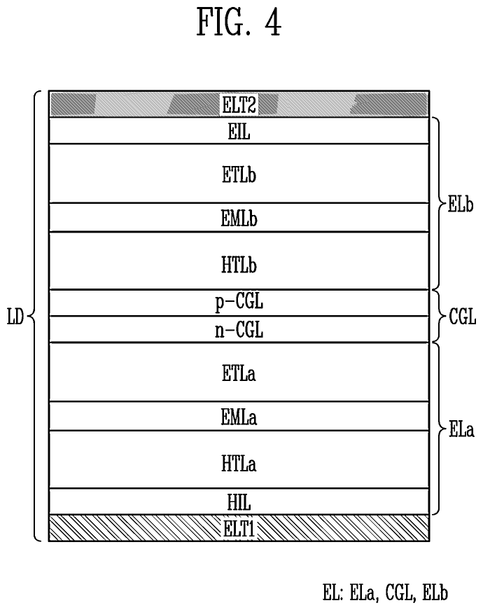

FIG. 2 is a schematic sectional view illustrating a display device in accordance with an embodiment of the disclosure. FIG. 3 is a schematic sectional view illustrating an embodiment of a light emitting element shown in FIG. 2. FIG. 4 is a schematic sectional view illustrating another embodiment of the light emitting element shown in FIG. 2.

Referring to FIG. 2, the display device DD includes a pixel circuit layer PCL and a light emitting element layer LEL.

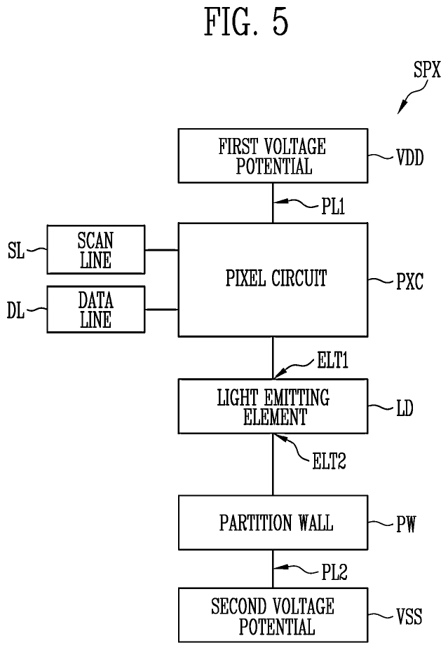

The pixel circuit layer PCL may be a layer including a pixel circuit PXC (see FIG. 5) for driving light emitting elements LD. The pixel circuit layer PCL may include a base layer BSL, conductive layers for forming pixel circuits, and insulating layers disposed between the conductive layers.

In some embodiments, the pixel circuit PXC may include circuit elements (e.g., a driving transistor and the like), and may be electrically connected to the light emitting elements LD to provide an electrical signal for allowing the light emitting elements LD to emit light.

The light emitting element layer LEL may be disposed on the pixel circuit layer PCL. In some embodiments, the light emitting element layer LEL may include a pixel defining layer PDL, partition walls PW, the light emitting elements LD, an auxiliary electrode AEL, and/or an encapsulation layer TFE.

The light emitting elements LD may be disposed on the pixel circuit layer PCL (or the base layer BSL). In some embodiments, each of the light emitting elements LD may include a first electrode ELT1, a light emitting portion EL, and a second electrode ELT2.

The first electrodes ELT1 may be disposed on the base layer BSL (or the pixel circuit layer PCL). The light emitting portions EL may be disposed on the first electrodes ELT1. The second electrodes ELT2 may be disposed on the light emitting portions EL.

In some embodiments, each of the light emitting elements EL may be disposed in an area (e.g., a first sub-pixel area SPXA1, a second sub-pixel area SPXA2, or a third sub-pixel area SPXA3, which is shown in FIG. 2) defined by the pixel defining layer PDL and the partition wall PW. Each of the light emitting portions EL may be disposed between the partition walls PW. The light emitting portion EL may be disposed adjacent to the partition wall PW. The light emitting portion EL may include a first light emitting portion EL1 for forming a first sub-pixel SPX1 emitting light of a first color, a second light emitting portion EL2 for forming a second sub-pixel SPX2 emitting light of a second color, and a third light emitting portion EL3 for forming a third sub-pixel SPX3 emitting light of a third color.

A surface of the light emitting portion EL may be electrically connected to the first electrode ELT1, and another surface of the light emitting portion EL may be electrically connected to the second electrode ELT2.

The first electrode ELT1 may be an anode electrode for the light emitting portion EL, and the second electrode ELT2 may be a cathode electrode for the light emitting portion EL. In some embodiments, the first electrode ELT1 and the second electrode ELT2 may include a conductive material. For example, the first electrode ELT1 may include a conductive material including reflexibility, and the second electrode ELT2 may include a transparent conductive material. However, the disclosure is not necessarily limited thereto. In some embodiments, the second electrode ELT2 may include at least one selected from the group consisting of silver (Ag) and magnesium (Mg). The first electrode ELT1 may be the cathode electrode for the light emitting portion EL, and the second electrode ELT2 may be the anode electrode for the light emitting portion EL.

Referring to FIG. 3, the light emitting portion EL may have a multi-layer thin film structure including a light generation layer (e.g., a light emitting layer EML). The light emitting portion EL may include a hole injection layer HIL for injecting holes, a hole transport layer HTL for increasing a hole recombination opportunity by suppressing movement of electrons which are excellent in transportability of holes and are not combined in the light emitting layer EML, the light emitting layer EML for emitting light by recombination of the injected electrons and holes, an electron transport layer ETL for smoothly transporting the electrons to the light emitting layer EML, and an electron injection layer EIL for injecting the electrons. The light emitting portion EL may emit light, based on an electrical signal provided from the anode electrode (e.g., the first electrode ELT1) and the cathode electrode (e.g., the second electrode ELT2).

In some embodiments, referring to FIG. 4, the light emitting element LD may include a tandem structure. For example, the light emitting portion EL may further include a first light emitting portion ELa, a charge generation layer CGL, and a second light emitting portion ELb.

The first light emitting portion ELa may be provided in a structure in which a hole injection layer HIL, a first hole transport layer HTLa, a first light emitting layer EMLa, and a first electron transport layer ETLa are sequentially stacked. The second light emitting portion ELb may be provided in a structure in which a second hole transport layer HTLb, a second light emitting layer EMLb, a second electron transport layer ETLb, and an electron injection layer EIL are sequentially stacked.

In an embodiment, a buffer layer (not shown) may be disposed on the first light emitting layer EMLa and the second light emitting layer EMLb. The buffer layer may include an electron transport compound.

The charge generation layer CGL may perform a function of supplying charges to the first light emitting portion ELa and the second light emitting portion ELb. The charge generation layer CGL may include an n-type charge generation layer n-CGL for supplying charges to the first light emitting portion ELa and a p-type charge generation layer p-CGL for supplying holes to the second light emitting portion ELb. The n-type charge generation layer n-CGL may include a metal material as a dopant.

In FIG. 4, it is illustrated that the light emitting element LD is provided such that two light emitting portions ELa and ELb of the light emitting element LD are stacked. However, the disclosure is not limited thereto. For example, the light emitting element LD may be provided such that three or four or more light emitting portions are stacked each other in the light emitting element LD.

The pixel defining layer PDL may be disposed on the pixel circuit layer PCL. The pixel defining layer PDL may define positions at which the light emitting portions EL are arranged. At least portions of the pixel defining layer PDL may be spaced apart from each other with the light emitting portions EL interposed therebetween. At least a portion of the pixel defining layer PDL may be disposed on the first electrode ELT1. The pixel defining layer PDL may be disposed adjacent to the first electrode ELT1. For example, the pixel defining layer PDL may be disposed adjacent to the first electrode ELT1 in a direction in which a plane on which the base layer BSL is disposed extends. At least a portion of the pixel defining layer PDL may expose at least a portion of the first electrode ELT1. At least a portion of the pixel defining layer PDL may overlap the first electrode ELT1 in a plan view. The pixel defining layer PDL may cover an end portion of the first electrode ELT1.

The pixel defining layer PDL may include an inorganic material. For example, the inorganic material may include at least one selected from the group consisting of silicon nitride (SiNₓ), silicon oxide (SiOₓ), silicon oxynitride (SiOₓN_{y}), and aluminum oxide (AlOₓ). However, the disclosure is not limited thereto. The pixel defining layer PDL may include an organic material. For example, the pixel defining layer PDL may include at least one selected from the group consisting of acrylic resin, epoxy resin, phenolic resin, polyamide resin, and polyimide resin.

The partition walls PW may be disposed on the pixel defining layer PDL. Each of the partition walls PW may be disposed between the light emitting portions EL. The partition walls PW may be disposed between adjacent sub-pixels SPX1, SPX2, and SPX3 or at boundaries of the adjacent sub-pixels SPX1, SPX2, and SPX3, to define the first sub-pixel area SPXA1, the second sub-pixel area SPXA2, and the third sub-pixel area SPXA3.

The partition wall PW may include a multi-stacked structure. In some embodiments, the partition wall PW may include a triple-layer structure. For example, the partition wall PW may include a first partition wall layer PW1, a second partition wall layer PW2, and/or a third partition wall layer PW3. However, the disclosure is not necessarily limited thereto. Hereinafter, a case where the partition wall PW has a triple-layer structure including the first partition wall layer PW1, the second partition wall layer PW2, and the third partition wall layer PW3 will be mainly described.

The first partition wall layer PW1, the second partition wall layer PW2, and the third partition wall layer PW3 may be stacked each other in a thickness direction of the base layer BSL (e.g., a third direction DR3). For example, the first partition wall layer PW1 may be disposed on the pixel defining layer PDL. In some embodiments, the first partition wall layer PW1 may be disposed directly on the pixel defining layer PDL. The second partition wall layer PW2 may be disposed on the first partition wall layer PW1. The second partition wall layer PW2 may contact the first partition wall layer PW1. The second partition wall layer PW2 may be disposed directly on the first partition wall layer PW1. The third partition wall layer PW3 may be disposed on the second partition wall layer PW2. The third partition wall layer PW3 may contact the second partition wall layer PW2. The third partition wall layer PW3 may be disposed directly on the second partition wall layer PW2.

The second partition wall layer PW2 may have a width narrower than a width of each of the first partition wall layer PW1 and the third partition wall layer PW3. For example, the first partition wall layer PW1 and the third partition wall layer PW3 may protrude outwardly of the second partition wall layer PW2 in the first direction DR1 or the second direction DR2. For example, the partition wall PW may have an I-shaped structure. For example, the partition wall PW may form a tip structure in which the second partition wall layer PW2 is retracted inwardly of the first partition wall layer PW1 and the third partition wall layer PW3.

In the disclosure, a width may be defined with respect to a direction (e.g., the first direction DR1 or the second direction DR2) in which a plane on which the base layer BSL is disposed extends.

As the partition wall PW has the tip structure, the light emitting portion EL may not overlap at least a partial area of a side surface of the second partition wall layer PW2 when viewed in the direction (e.g., the first direction DR1 or the second direction DR2) in which the plane on which the base layer BSL is disposed extends. Due to the tip structure of the partition wall PW, when organic materials for forming the light emitting portions EL are deposited, at least portions of the light emitting portions EL may be separated from each other, and the sub-pixels SPX1, SPX2, and SPX3 may be distinguished from each other. For example, the light emitting portion EL may be separated into the first light emitting portion EL1, the second light emitting portion EL2, and the third light emitting portion EL3.

The second partition wall layer PW2 may have a thickness thicker than a thickness of each of the first partition wall layer PW1 and the third partition wall layer PW3. For example, as the second partition wall layer PW2 is formed thick, when the light emitting portion EL is formed, the light emitting portion EL may not overlap the third partition wall layer PW3 when viewed in a direction in which a plane on which the base layer BSL is disposed extends (e.g., a direction in which a plane defined by the first direction DR1 and the second direction DR2 extends). The light emitting portion EL may be relatively adjacent to the base layer BSL as compared with the third partition wall layer PW3 formed at a position relatively high with respect to the base layer BSL.

In the disclosure, a thickness may be defined with respect to the thickness direction of the base layer BSL (e.g., the third direction DR3).

In some embodiments, the first partition wall layer PW1 may have a thickness in a range of about 30 Å to about 100 Å. In some embodiments, the second partition wall layer PW2 may have a thickness in a range of about 4000 Å to about 10000 Å. In some embodiments, the third partition wall layer PW3 may have a thickness in a range of about 500 Å to about 2000 Å.

The first partition wall layer PW1 may include a Transparent Conductive Oxide (TCO) material. In some embodiments, the TCO material may include at least one selected from the group consisting of Indium Tin Oxide (ITO), Indium Zinc Oxide (IZO), Indium Gallium Zinc Oxide (IGZO), and Aluminum Zinc Oxide (AZO). However, the disclosure is not limited thereto. The TCO material may include various materials in the art, such as an Indium Oxide (InₓO_{y})-based material, a Zinc Oxide (ZnₓO_{y})-based material, and a Tin Oxide (SnₓO_{y})-based material. In the disclosure, the TCO material included in the first partition wall layer PW1 may be defined as a first TCO material.

The second partition wall layer PW2 may include a metal material. For example, the metal material may include at least one selected from the group consisting of gold (Au), silver (Ag), aluminum (Al), molybdenum (Mo), chromium (Cr), titanium (Ti), nickel (Ni), neodymium (Nd), copper (Cu), and platinum (Pt). In some embodiments, the second partition wall layer PW2 may include a reflective metal material. For example, the reflective metal material may include at least one selected from the group consisting of silver (Ag), aluminum (Al), and platinum (Pt).

As the second partition wall layer PW2 includes the reflective metal material, the second partition wall layer PW2 may reflect light emitted from the light emitting portion EL to advance toward the third partition wall layer PW3.

Experimentally, in case that the second partition wall layer PW2 includes the reflective metal material, adhesion between the pixel defining layer PDL and the second partition wall layer PW2 may be weakened as the second partition wall layer PW2 is disposed directly on the pixel defining layer PDL. In the display device DD in accordance with the embodiment of the disclosure, the second partition wall layer PW2 may be disposed directly on the first partition wall layer PW1, to be stably attached on the first partition wall layer PW1.

The third partition wall layer PW3 may include a TCO material. In some embodiments, the third partition wall layer PW3 may include an amorphous TCO material. In some embodiments, the amorphous TCO material may include at least one selected from the group consisting of Indium Zinc Oxide (IZO) and Indium Gallium Zinc Oxide (IGZO). In the disclosure, the TCO material included in the third partition wall layer PW3 may be defined as a second TCO material. For example, the third partition wall layer PW3 may include a TCO material defined independently from the first TCO material of the first partition wall layer PW1. The first TCO material and the second TCO material may be different from each other or may be the same in some embodiments.

Conventionally, as a layer disposed at an uppermost portion of the partition wall PW included a metal material (e.g., titanium (Ti)) which is not transparent, light emitted from the light emitting portion EL was blocked by the layer disposed at the uppermost portion of the partition wall PW. On the other hand, the third partition wall layer PW3 of the disclosure may include the TCO material, so that light emitted from the light emitting portion EL and reflected from the second partition wall layer PW2 can be transmitted through the third partition wall layer PW3. Accordingly, the light emission efficiency of the display device DD can be improved.

A partition wall insulating layer IL may cover (or overlap) a side surface (e.g., an outer side surface) of the partition wall PW. The side surface of the partition wall PW may be a surface of the partition wall PW in a direction perpendicular to the base layer BSL. The partition wall insulating layer IL may entirely cover a side surface of each of the first partition wall layer PW1, the second partition wall layer PW2, and the third partition wall layer PW3. The partition wall insulating layer IL may be disposed directly on the side surface of each of the first partition wall layer PW1, the second partition wall layer PW2, and the third partition wall layer PW3.

The partition wall insulating layer IL may not cover a top surface of the third partition wall layer PW3. The partition wall insulating layer IL may expose the top surface of the third partition wall layer PW3. The top surface of the third partition wall layer PW3 may be a surface opposite to a surface facing the base layer BSL. For example, the top surface of the third partition wall layer PW3 may be a surface not facing the pixel circuit layer PCL.

In the disclosure, a top surface may be a surface opposite to a surface facing the pixel circuit layer PCL (or the base layer BSL). A bottom surface may be a surface facing the pixel circuit layer PCL (or the base layer BSL).

The partition wall insulating layer IL may contact at least a portion of the pixel defining layer PDL. The partition wall insulating layer IL may contact at least a portion of the light emitting portion EL. The partition wall insulating layer IL may not contact the first electrode ELT1. The partition wall insulating layer IL may not cover at least one surface (e.g., a top surface S1) of the light emitting portion EL. The partition wall insulating layer IL may not contact the top surface S1 of the light emitting portion EL. The partition wall insulating layer IL may not overlap at least a portion of the light emitting portion EL in a plan view. The partition wall insulating layer IL may contact at least a portion of a side surface of the light emitting portion EL. At least an area of the partition wall insulating layer IL may be disposed downwardly of the top surface S1 of the light emitting portion EL.

The partition wall insulating layer IL may be a transparent insulating layer. The partition wall insulating layer IL may include an inorganic material. For example, the partition wall insulating layer IL may include at least one selected from the group consisting of silicon oxide (SiOₓ) and aluminum oxide (AlOₓ). For example, the partition wall insulating layer IL may include at least one selected from the group consisting of silica (SiO₂) and aluminum oxide (Al₂O₃).

The partition wall insulating layer IL may have a thickness in a range of about 100 Å to about 500 Å.

In the display device DD of the disclosure, as the partition wall insulating layer IL is formed to cover the side surface of the partition wall PW, a risk that a leakage current flowing between the partition walls PW may be generated can be reduced even in case that a distance between the partition walls PW is narrowed to a micro scale or nano scale size. For example, a risk that a current flowing from the first light emitting portion EL1 to the second light emitting portion EL2, from the second light emitting portion EL2 to the third light emitting portion EL3, or from the first light emitting portion ELI to the third light emitting portion EL3 may be generated can be reduced.

In some embodiments, the display device DD may further include an upper second electrode UELT2. The upper second electrode UELT2 may be disposed on the partition wall PW. In the disclosure, the upper second electrode UELT2 may be a layer formed in the same deposition process as the second electrode ELT2 disposed between the partition walls PW. The upper second electrode UELT2 may be disposed on the third partition wall layer PW3. The upper second electrode UELT2 may overlap at least a portion of the third partition wall layer PW3 in a plan view.

In some embodiments, the display device DD may further include an upper light emitting portion (not shown). The upper light emitting portion may be disposed on the third partition wall layer PW3. In the disclosure, the upper light emitting portion may be a layer including the same material as the light emitting portion EL emitting light as a layer formed in the same deposition process as the light emitting portion EL. In this drawing, it is illustrated that the upper second electrode UELT2 is disposed directly on the third partition wall layer PW3. However, in some embodiments, the upper light emitting portion may be disposed between the third partition wall layer PW3 and the upper second electrode UELT2. In some embodiments, the upper light emitting portion may cover (or overlap) at least a portion of the third partition wall layer PW3. In some embodiments, the upper light emitting portion may expose at least a portion of the third partition wall layer PW3.

The display device DD may further include the auxiliary electrode AEL. The auxiliary electrode AEL may be disposed on the second electrode ELT2. The auxiliary electrode AEL may be disposed on (e.g., directly on) the second electrode ELT2, at least a portion of the partition wall insulating layer IL, and the upper second electrode UELT2. The auxiliary electrode AEL may entirely cover (or overlap) the second electrode ELT2, the at least a portion of the partition wall insulating layer IL, and the upper second electrode UELT2. The auxiliary electrode AEL may contact the second electrode ELT2, the at least a portion of the partition wall insulating layer IL, and the upper second electrode UELT2. The auxiliary electrode AEL may not contact the side surface of the partition wall PW.

The auxiliary electrode AEL may have a thickness in a range of about 25 Å to about 100 Å.

The auxiliary electrode AEL may be a transparent conductive layer. The auxiliary electrode AEL may include a transparent metal material. In some embodiments, the auxiliary electrode AEL may be a thin film metal layer. In some embodiments, the auxiliary electrode AEL may include at least one selected from the group consisting of a TCO material (e.g., Indium Tin Oxide (ITO), Indium Zinc Oxide (IZO), Indium Gallium Zinc Oxide (IGZO), or Aluminum Zinc Oxide (AZO)) and titanium nitride (TiN). In some embodiments, the auxiliary electrode AEL may include Indium Tin Oxide (ITO) or Titanium Nitride (TiN). In the disclosure, the TCO material included in the auxiliary electrode AEL may be defined as a third TCO material. In some embodiments, the third TCO material may be different from the first TCO material and the second TCO material, or may be the same as the first TCO material and the second TCO material.

The auxiliary electrode AEL may electrically connect the second electrode ELT2 and the partition wall PW to each other. Accordingly, the auxiliary AEL can prevent the second electrode ELT2 from being electrically disconnected by the partition wall PW.

The encapsulation layer TFE may be disposed over the auxiliary electrode AEL. The encapsulation layer TFE may cancel a step difference (or height difference) generated by the light emitting element LD and the pixel defining layer PDL. The encapsulation layer TFE may include insulating layers covering the light emitting element LD. In some embodiments, the encapsulation layer TFE may have a structure in which an inorganic layer and an organic layer are alternately stacked each other. In some embodiments, the encapsulation layer TFE may be a thin film encapsulation film.

In some embodiments, the display device DD may further include an optical functional layer, an overcoat layer, and/or a cover window, which are disposed on the encapsulation layer TFE. However, the structure of the display device DD is not necessarily limited to the above-described example.

FIG. 5 is a schematic block diagram illustrating an electrical connection structure of a light emitting element in accordance with an embodiment of the disclosure. For example, FIG. 5 may illustrate an electrical connection structure including a pixel circuit PXC corresponding to each sub-pixel SPX.

Referring to FIG. 5, the sub-pixel SPX may include a pixel circuit PXC configured to drive a light emitting element LD.

The pixel circuit PXC may include at least one circuit element. For example, the pixel circuit PXC may include transistors and a storage capacitor. For example, the pixel circuit PXC may include a driving transistor, a switching transistor, and a storage capacitor. However, the disclosure is not necessarily limited thereto.

The pixel circuit PXC may be electrically connected to a scan line SL and a data line DL. The scan line SL may supply a scan signal to the pixel circuit PXC. In some embodiments, the scan line SL may be electrically connected to a gate electrode of the switching transistor of the pixel circuit PXC. The light emitting element LD may be configured to emit light corresponding to a data signal provided from the data line DL.

The pixel circuit PXC may be electrically connected to a first power line PL1 and a second power line PL2. For example, a first electrode ELT1 of the light emitting element LD may be electrically connected to the pixel circuit PXC and the first power line PL1, and a second electrode ELT2 of the light emitting element LD may be electrically connected to the second power line PL2. In some embodiments, the second power line PL2 may be formed in the pixel circuit layer PCL in the display area DA. As another example, in other embodiments, the second power line PL2 may be disposed in the non-display area NDA. Accordingly, the second power line PL2 may be configured to supply a second power source to the light emitting element LD.

A power source of the first power line PL1 and a power source of the second power line PL2 may have different potentials. For example, the power source of the first power line PL1 may be a high-potential pixel power source supplied with a power source from a first voltage potential VDD, and the power source of the second power line PL2 may be a low-potential pixel power source supplied with a power source from a second voltage potential VSS. A potential difference between the power source of the first power line PL1 and the power source of the second power line PL2 may be set substantially equal to or higher than a threshold voltage of light emitting elements LD.

The first power line PL1 may be electrically connected to the pixel circuit PXC (e.g., the driving transistor). The second power line PL2 may be electrically connected to a cathode electrode (e.g., the second electrode ELT2) of the light emitting element LD.

In some embodiments, the second power line PL2 may be electrically connected to the second electrode ELT2 through a partition wall PW. For example, the partition wall PW may electrically connect the second electrode ELT2 and the second power line PL2 to each other.

Light emitting elements LD may be electrically connected in a forward direction between the first power line PL1 and the second power line PL2, to respectively form effective light sources. These effective light sources may gather to constitute the light emitting elements LD of the sub-pixel SPX.

The light emitting elements LD may emit light with a luminance corresponding to a driving current supplied through the pixel circuit PXC. The pixel circuit PXC may supply a driving current corresponding to the data signal to the light emitting element LD during each frame period. The light emitting element LD may emit light with a luminance corresponding to a current flowing therethrough.

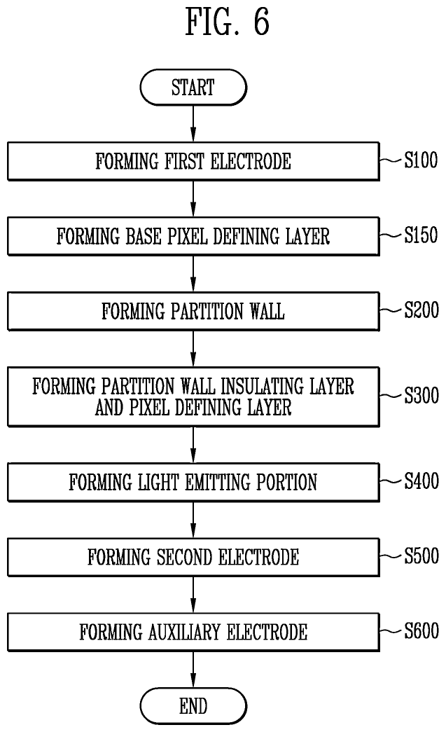

Hereinafter, a method of manufacturing the display device DD will be described with reference to FIGS. 6 to 14.

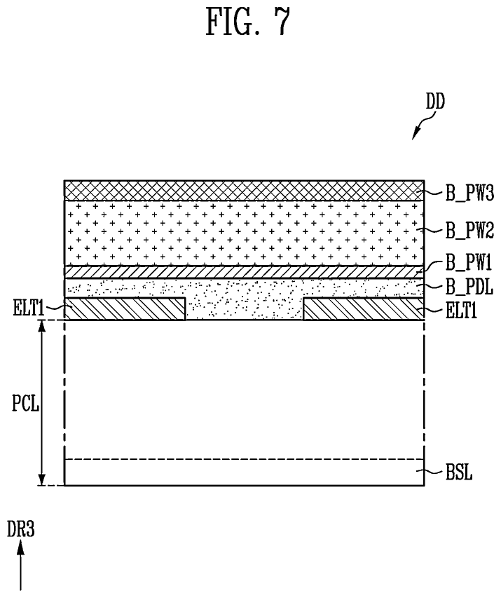

FIG. 6 is a schematic flowchart illustrating a method of manufacturing the display device in accordance with an embodiment of the disclosure. FIGS. 7 to 14 are schematic sectional views illustrating process steps of the method of manufacturing the display device in accordance with an embodiment of the disclosure.

Referring to FIG. 6, the method of manufacturing the display device DD may include step S100 of forming a first electrode, step S150 of forming a base pixel defining layer, step S200 of forming a partition wall, step S300 of forming a partition wall insulating layer and a pixel defining layer, step S400 of forming a light emitting portion, step S500 of forming a second electrode, and step S600 of forming an auxiliary electrode.

Referring to FIG. 7, in the step S100 of forming the first electrode, first electrodes ELT1 may be patterned on a base layer BSL (or a pixel circuit layer PCL).

Before the first electrodes ELT1 are patterned, the pixel circuit layer PCL including a pixel circuit PXC for driving light emitting elements LD may be formed (e.g., patterned) on the base layer BSL. The pixel circuit layer PCL may be formed (e.g., patterned) to include conductive layers and insulating layers disposed between the conductive layers.

In some embodiments, components disposed on the base layer BSL may be formed (e.g., patterned) through an ordinary patterning process (e.g., a photolithography process or the like) using a mask.

In the step S100 of forming the first electrode, the first electrodes ELT1 may be formed (e.g., patterned) on the pixel circuit layer PCL (or the base layer BSL). In some embodiments, the first electrodes ELT1 may be deposited on the pixel circuit layer PCL, to be etched such that at least a portion of the pixel circuit layer PCL is exposed.

In the disclosure, at least one of a Chemical Vapor Deposition (CVD) process and an Atomic Layer Deposition (ALD) process may be used as a process for depositing a component of the display device DD unless otherwise described herein. In the disclosure, at least one of a wet etching process and a dry etching process may be used as an etching process unless otherwise described herein. However, the disclosure is not limited to a specific example.

Although not shown in the drawing, in some embodiments, when the first electrode ELT1 is formed (e.g., patterned), the first electrode ELT1 may be electrically connected to a driving transistor through a hole penetrating a protective layer in the pixel circuit layer PCL.

After the first electrode ELT1 is formed (e.g., patterned), in the step S150 of forming the base pixel defining layer, a base pixel defining layer B_PDL for forming (e.g., patterning) a pixel defining layer PDL may be formed (or disposed) over the first electrodes ELT1. The step S150 of forming the base pixel defining layer may include a step of forming (or disposing) the base pixel defining layer B_PDL to cover the first electrodes ELT1.

After the base pixel defining layer B_PDL is formed (or disposed), in the step S200 of forming the partition wall, a partition wall PW may be formed (e.g., patterned). The step S200 of forming the partition wall may include a step of depositing a first base partition wall layer B_PW1, a step of depositing a second base partition wall layer B_PW2, and a step of depositing a third base partition wall layer B_PW3.

The step of depositing the first base partition wall layer B_PW1 may include a step of forming (or disposing) the first base partition wall layer B_PW1 on the base pixel defining B_PDL. The first base partition wall layer B_PW1 may be formed (or disposed) directly on the base pixel defining layer B_PDL to entirely cover the base pixel defining layer B_PDL. The first base partition wall layer B_PW1 may be deposited to have a thickness in a range of about 30 Å to about 100 Å.

In the disclosure, the first base partition wall layer B_PW1 may be a layer for forming a first partition wall layer PW1, and the first base partition wall layer B_PW1 and the first partition wall layer PW1 may include a same material. For example, the first base partition wall layer B_PW1 may include a TCO material.

As the first base partition wall layer B_PW1 includes the TCO material, adhesion of the second base partition wall layer B_PW2 to be deposited on the first base partition wall layer B_PW1 may be increased as compared with a case that the second base partition wall layer B_PW2 is disposed directly on the base pixel defining layer B_PDL.

The step of depositing the second base partition wall layer B_PW2 may include a step of forming (or disposing) the second base partition wall layer B_PW2 on the first base partition wall layer B_PW1. The second base partition wall layer B_PW2 may be formed (or disposed) on the first base partition wall layer B_PW1 to entirely cover the first base partition wall layer B_PW1. The second base partition wall layer B_PW2 may be deposited to have a thickness in a range of about 4000 Å to about 10000 Å.

In the disclosure, the second base partition wall layer B_PW2 may be a layer for forming a second partition wall layer PW2, and the second base partition wall layer B_PW2 and the second partition wall layer PW2 may include a same material. For example, the second base partition wall layer B_PW2 may include a reflective metal material. For example, the second base partition wall layer B_PW2 may include at least one selected from the group consisting of silver (Ag), aluminum (Al), and platinum (Pt).

The step of depositing the third base partition wall layer B_PW3 may include a step of forming (or disposing) the third base partition wall layer B_PW3 on the second base partition wall layer B_PW2. The third base partition wall layer B_PW3 may be formed (or disposed) directly on the second base partition wall layer B_PW2 to entirely cover the second base partition wall layer B_PW2. The third base partition wall layer B_PW3 may be deposited to have a thickness in a range of about 500 Å to about 2000 Å.

In the disclosure, the third base partition wall layer B_PW3 may be a layer for forming a third partition wall layer PW3, and the third base partition wall layer B_PW3 and the third partition wall layer PW3 may include a same material. For example, the third base partition wall layer B_PW3 may include a TCO material. In some embodiments, the third base partition wall layer B_PW3 may include an amorphous TCO material. In some embodiments, the amorphous TCO material may include at least one selected from the group consisting of Indium Zinc Oxide (IZO) and Indium Gallium Zinc Oxide (IGZO).

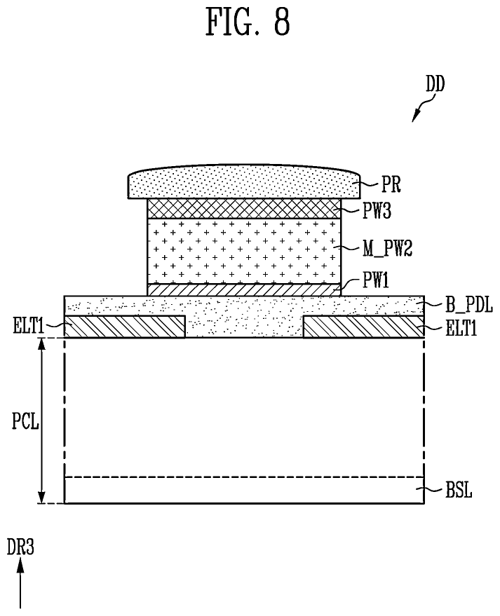

Referring to FIG. 8, the step S200 of forming the partition wall may further include a step of disposing a photoresist PR on the third base partition wall layer B_PW3 and a step of etching the third base partition wall layer B_PW3, the second base partition wall layer B_PW2, and the first base partition wall layer B_PW1.

The step of disposing the photoresist PR on the third base partition wall layer B_PW3 may include a step of disposing the photoresist PR to cover at least a portion of the third base partition wall layer B_PW3. The photoresist PR may be disposed to expose at least a portion of the third base partition wall layer B_PW3 (e.g., a portion of the top of the third base partition wall layer B_PW3).

The step of etching the third base partition wall layer B_PW3, the second base partition wall layer B_PW2, and the first base partition wall layer B_PW1 may include a step of forming (e.g., patterning) the third partition wall layer PW3 by etching the third base partition wall layer B_PW3, a step of forming (e.g., patterning) a second middle partition wall layer M_PW2 by etching the second base partition wall layer B_PW2, and a step of forming (e.g., patterning) the first partition wall layer PW1 by etching the first base partition wall layer B_PW1.

In the disclosure, the second middle partition wall layer M_PW2 may be a layer formed by performing a one-time etching process on the second base partition wall layer B PW2.

The third base partition wall layer B_PW3, the second base partition wall layer B_PW2, and the first base partition wall layer B_PW1 may be collectively wet-etched.

The first partition wall layer PW1, the second middle partition wall layer M_PW2, and the third partition wall layer PW3 may have the same end portion(s). For example, end portions of the first partition wall layer PW1, the second middle partition wall layer M_PW2, and the third partition wall layer PW3 may accord with each other. The end portions of the first partition wall layer PW1, the second middle partition wall layer M_PW2, and the third partition wall layer PW3 may overlap each other in a plan view. Edges of the first partition wall layer PW1, the second middle partition wall layer M_PW2, and the third partition wall layer PW3 may correspond to each other. Side surfaces of the first partition wall layer PW1, the second middle partition wall layer M_PW2, and the third partition wall layer PW3 may form a same surface.

In some embodiments, in case that the third base partition wall layer B_PW3 includes an amorphous TCO material, the third base partition wall layer B_PW3 may be relatively readily etched as compared with a case that the third base partition wall layer B_PW3 does not include the amorphous TCO material, even though the third base partition wall layer B_PW3 is deposited to have a thickness exceeding about 250 Å. For example, in case that the third base partition wall layer B_PW3 includes the amorphous TCO material, the third base partition wall layer B_PW3 may be etched within a short time as compared with a case that the base partition wall layer B_PW3 does not include the amorphous TCO material.

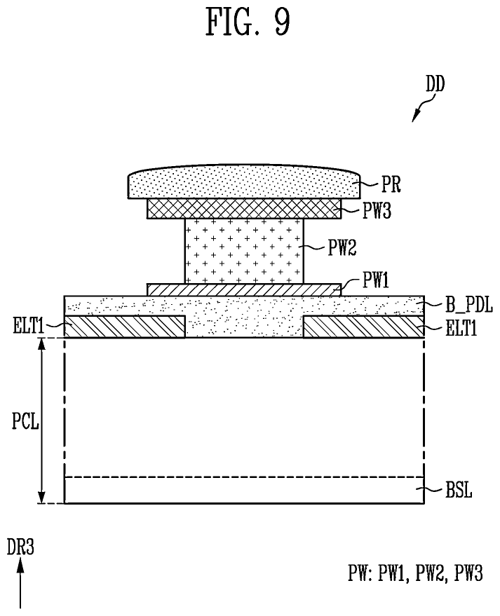

Referring to FIG. 9, the step S200 of forming the partition wall may further include a step of etching the second middle partition wall layer M_PW2. The step of etching the second middle partition wall layer M_PW2 may further include a step of further wet-etching the second middle partition wall layer M_PW2, using an etchant for etching only the second middle partition wall layer M_PW2. In the step of etching the second middle partition wall layer M_PW2, the second partition wall layer PW2 may be formed (e.g., patterned) by etching the second middle partition wall layer M_PW2.

For example, in case that the second base partition wall layer B_PW2 includes silver (Ag), the second middle partition wall layer M_PW2 may be wet-etched using an etchant which etches the silver (Ag) and does not etch any materials included in the first base partition wall layer B_PW1 and the third base partition wall layer B_PW3.

In the step of etching the second middle partition wall layer M_PW2, the second middle partition wall layer M_PW2 may be further etched to have a structure in which the second partition wall layer PW2 is retracted inwardly (e.g., in a width direction) of the first partition wall layer PW1 and the third partition wall layer PW3. For example, the second middle partition wall layer M_PW2 may be etched such that the first partition wall layer PW1 and the third partition wall layer PW3 protrude outwardly of the second partition wall layer PW2 in the first direction DR1 or the second direction DR2.

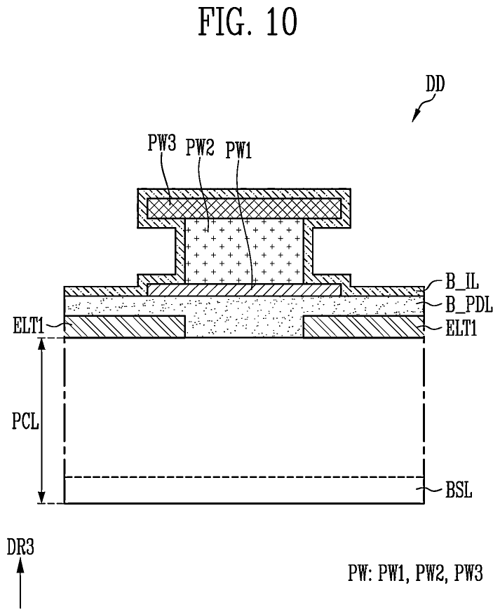

Referring to FIG. 10, the step S300 of forming the partition wall insulating layer and the pixel defining layer may include a step of forming (e.g., patterning) a base partition wall insulating layer B_IL. The base partition wall insulating layer B_IL may be deposited to cover the partition wall PW and the base pixel defining layer B_PDL. For example, the base partition wall insulating layer B_IL may be deposited to cover a side surface of each of the first partition wall layer PW1, the second partition wall layer PW2, and the third partition wall layer PW3, a top surface of the third partition wall layer PW3, and at least a portion of a top surface of the base pixel defining layer B_PDL. The base partition wall insulating layer B_IL may be deposited to have a thickness in a range of about 100 Å to about 500 Å.

In the disclosure, the base partition wall insulating layer B_IL may be a layer for forming a partition wall insulating layer IL, and the base partition wall insulating layer B_IL and the partition wall insulating layer IL may include a same material. For example, the base partition wall insulating layer B_IL may include an inorganic material. For example, the base partition wall insulating layer B_IL may include at least one selected from the group consisting of silicon oxide (SiOₓ) and aluminum oxide (AlOₓ). For example, the base partition wall insulating layer B_IL may include at least one selected from the group consisting of silica (SiO₂) and aluminum oxide (Al₂O₃).

In case that the base partition wall insulating layer B_IL includes a material except a metal (e.g., silicon oxide (SiOₓ)) (in some embodiments, silica (SiO₂)), the base partition wall insulating layer B_IL may be deposited through a CVD process. In case that the base partition wall insulating layer B_IL includes a material including a metal (e.g., aluminum oxide (AlOₓ)) (in some embodiments, aluminum oxide (Al₂O₃)), the base partition wall insulating layer B_IL may be deposited through an ALD process. In some embodiments, in case that the base partition wall insulating layer B_IL includes a metal, the base partition wall insulating layer B_IL may be deposited through the ALD process to have a uniform thickness as compared with a case that the base partition wall insulating layer B_IL is deposited through the CVD process. For example, in case that the base partition wall insulating layer B_IL includes aluminum oxide (Al₂O₃), the base partition wall insulating layer B_IL may be deposited through the ALD process to have a uniform thickness as compared with a case that the base partition wall insulating layer B_IL is deposited through the CVD process.

A case where the base partition wall insulating layer B_IL includes at least one selected from the group consisting of silica (SiO₂) and aluminum oxide (Al₂O₃) will be described. In a subsequent process of forming (e.g., patterning) a light emitting portion EL, when an encapsulation layer is formed (e.g., patterned) over the light emitting portion EL and the partition wall PW, and the encapsulation layer disposed on the top of the partition wall PW is etched, an etch rate of the encapsulation layer with respect to the partition wall insulating layer IL may be relatively high as compared with in case that the base partition wall insulating layer B_IL includes another material. For example, in case that an etch rate of the encapsulation layer with respect to the base partition wall insulating layer IL is high, the encapsulation layer may be etched, and the partition wall insulating layer IL disposed on the partition wall PW may not be etched. Thus, the partition wall insulating layer IL can properly protect the partition wall PW.

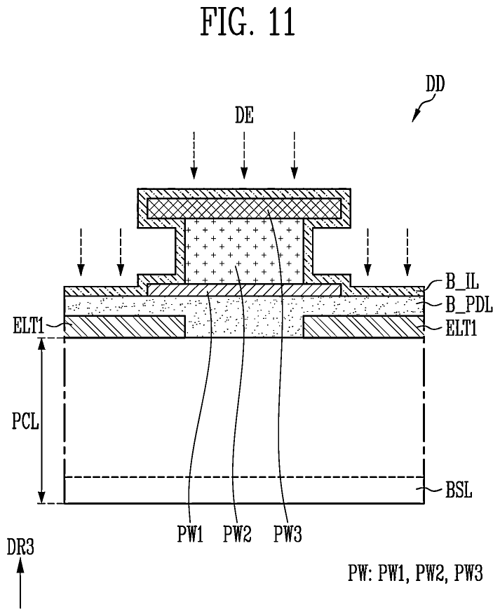

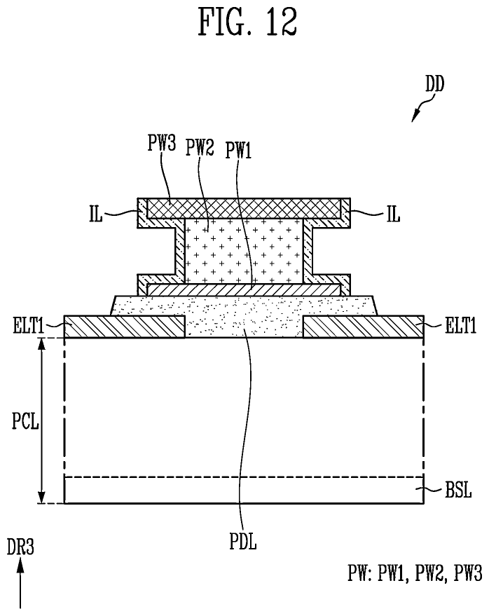

Referring to FIGS. 11 and 12, the step S300 of forming the partition wall insulating layer IL and the pixel defining layer PDL may include a step of performing dry etching (DE) on the base partition wall insulating layer B_IL and the base pixel defining layer B_PDL. The base partition wall insulating layer B_IL may be etched to form (e.g., pattern) the partition wall insulating layer IL. When the base partition wall insulating layer B_IL is etched in the step of forming the partition wall insulating layer IL, the base pixel defining layer B_PDL may also be etched, to form (e.g., pattern) the pixel defining layer PDL. The partition wall insulating layer IL and the pixel defining layer PDL may be formed (e.g., patterned) in the same dry etching process.

The step S300 of forming the partition wall insulating layer IL and the pixel defining layer PDL may include a step of etching portions of the base partition wall insulating layer B_IL contacting the base pixel defining layer B_PDL and the base partition wall insulating layer B_IL contacting the top surface of the third partition wall layer PW3 and a step of etching the base pixel defining layer B_PDL.

The step of forming (e.g., patterning) the pixel defining layer PDL may include a step of removing at least a portion of the base pixel defining layer B_PDL and a step of exposing, by the pixel defining layer PDL, at least a portion of the first electrode ELT1. The first electrode ELT1 and the top surface of the third partition wall layer PW3 may be exposed by etching at least a portion of the base partition wall insulating layer B_IL contacting the base pixel defining layer B_PDL, at least a portion of the base partition wall insulating layer B_IL contacting the top surface of the third partition wall layer PW3, and at least a portion of the base pixel defining layer B_PDL. For example, at least a portion of the first electrode ELT1 may be exposed by etching the base partition wall insulating layer B_IL and the base pixel defining layer B_PDL, which overlap the at least a portion of the first electrode ELT1 in a plan view. The third partition wall layer PW3 may be exposed by etching the base partition wall insulating layer B_IL contacting the top surface of the third partition wall layer PW3.

The partition wall insulating layer IL may cover (or overlap) a side surface of the partition wall PW by etching the base partition wall insulating layer B_IL. The partition wall insulating layer IL may entirely cover the side surface of each of the first partition wall layer PW1, the second partition wall layer PW2, and the third partition wall layer PW3. The step of forming the partition wall insulating layer IL and the step of removing the at least a portion of the base pixel defining layer B_PDL may be performed in the same dry etching process.

In some embodiments, in case that the third partition wall layer PW3 includes Indium Zinc Oxide (IZO), a rate at which the third partition wall layer PW3 is etched may be decreased when the base partition wall insulating layer B_IL is etched. For example, an etch selectivity of the base partition wall insulating layer B_IL with respect to the third partition wall layer PW3 may be high as compared with a case that the third partition wall layer PW3 includes another material. For example, the base partition wall insulating layer B_IL may be etched, and the third partition wall layer PW3 may not be etched.

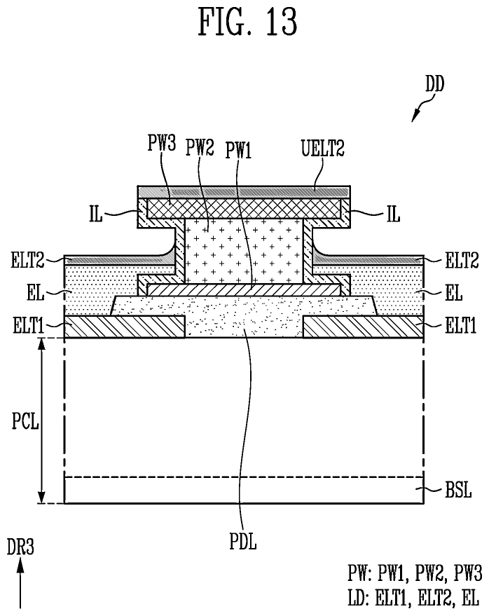

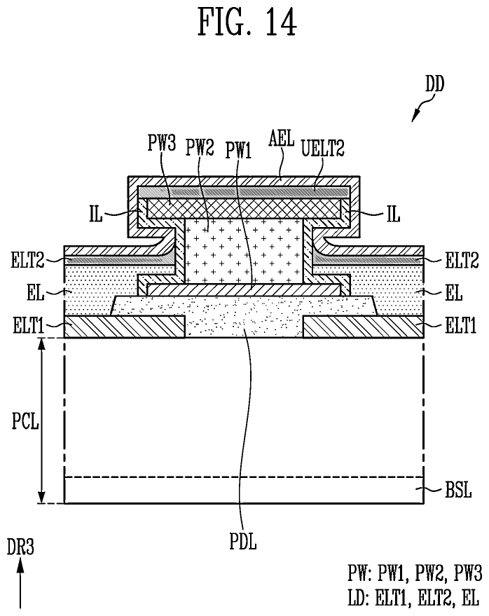

Referring to FIGS. 13 and 14, the step S400 of forming a light emitting portion may include a step of forming (e.g., patterning) light emitting portions EL. The light emitting portions EL may be formed (e.g., patterned) adjacent to the partition wall PW in a direction in which a plane on which the base layer BSL is disposed extends. In conjunction with FIG. 2, a first light emitting portion EL1, a second light emitting portion EL2, and a third light emitting portion EL3 may be formed (e.g., patterned) in different processes. For example, after the first light emitting portion EL1 is deposited, the second light emitting portion EL2 may be deposited. After the second light emitting portion EL2 is deposited, the third light emitting portion EL3 may be deposited. However, the order in which the light emitting portions EL are deposited is not limited thereto. In some embodiments, the third light emitting portion EL3 may be deposited first (or before other light emitting portions). The light emitting portion EL may be deposited not to exceed the third partition wall layer PW3.

In some embodiments, in the step of forming (e.g., patterning) the light emitting portions EL, an upper light emitting portion may be formed (e.g., patterned) by depositing at least a portion of the light emitting portion EL on the third partition wall layer

PW3 when the light emitting portion is deposited. In some embodiments, the upper light emitting portion may be removed (or etched) in a process.

In the step S500 of forming the second electrode, a second electrode ELT2 may be deposited on the light emitting portion EL. In the step S500 of forming the second electrode, an upper second electrode UELT2 may be deposited on the third partition wall layer PW3. The upper second electrode UELT2 may be formed (e.g., patterned) in the same process as the second electrode ELT2. The second electrode ELT2 may be deposited to have a thickness in a range of about 100 Å to about 200 Å.

In the step S600 of forming the auxiliary electrode, an auxiliary electrode AEL may be deposited on the second electrode ELT2 through an ALD process. The auxiliary electrode AEL may be deposited to entirely cover the second electrode ELT2, at least a portion of the partition wall insulating layer IL, and the upper second electrode UELT2. The auxiliary electrode AEL may be disposed directly on the second electrode ELT2 to be electrically connected to the second electrode ELT2. The auxiliary electrode AEL may be deposited to have a thickness in a range of about 25 Å to about 100 Å. As the auxiliary electrode AEL is deposited through the ALD process, the auxiliary electrode AEL may be deposited to have a relatively uniform thickness, and be deposited to entirely cover the second electrode ELT2.

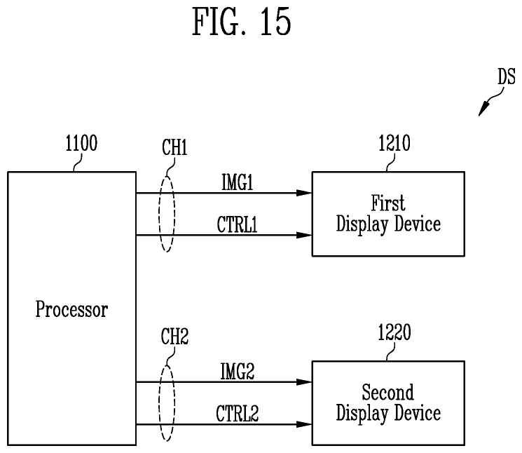

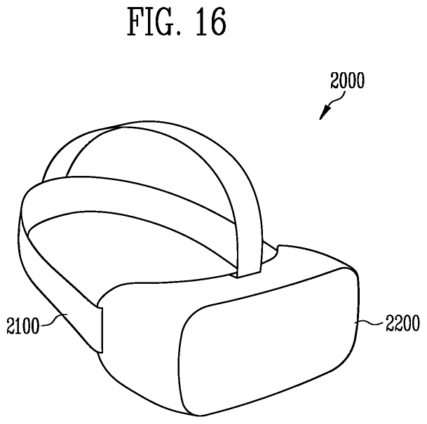

Hereinafter, a display system DS to which the display device DD is applicable will be described with reference to FIGS. 15 and 16.

FIG. 15 is a schematic block diagram of a display system in accordance with an embodiment of the disclosure. FIG. 16 is a schematic perspective view illustrating an application example of the display system shown in FIG. 15.

Referring to FIG. 15, the display system DS may include a processor 1100 and one or more display devices 1210 and 1220.

The processor 1100 may perform various tasks and various calculations. In embodiments, the processor 1100 may include an Application Processor (AP), a Graphics Processing Unit (GPU), a microprocessor, a Central Processing Unit (CPU), and the like. The processor 1100 may be electrically connected to other components of the display system DS through a bus system to control the components of the display system DS.

In FIG. 15, it is illustrated that the display system DS includes first and second display devices 1210 and 1220. The processor 1100 may be electrically connected to the first display device 1210 through a first channel CH1, and be electrically connected to the second display device 1220 through a second channel CH2.

Through the first channel CH1, the processor 1100 may transmit first image data IMG1 and a first control signal CTRL1 to the first display device 1210. The first display device 1210 may display an image, based on the first image data IMG1 and the first control signal CTRL1. The first display device 1210 may be configured identically to the display device DD described with reference to FIG. 1. The first image data IMG1 and the first control signal CTRL1 may be provided to the display device DD shown in FIG. 1.

Through the second channel CH2, the processor 1100 may transmit second image data IMG2 and a second control signal CTRL2 to the second display device 1220. The second display device 1220 may display an image, based on the second image data IMG2 and the second control signal CTRL2. The second display device 1220 may be configured identically to the display device DD described with reference to FIG. 1. The second image data IMG2 and the second control signal CTRL2 may be provided to the display device DD shown in FIG. 1.

The display system DS may include a computing system for providing an image display function, such as a portable computer, a mobile phone, a smartphone, a tablet personal computer (PC), a smart watch, a watch phone, a portable multimedia player (PMP), a navigation system, or an ultra-mobile personal computer (UMPC). Also, the display system DS may include at least one of a head mounted display (HMD) device, a virtual reality (VR) device, a mixed reality (MR) device, and an augmented reality (AR) device.

Referring to FIG. 16, the display system DS shown in FIG. 15 may be applied to a head mounted display device 2000. The head mounted display device 2000 may be a wearable electronic device which can be worn on a head of a user.

The head mounted display device 2000 may include a head mounting band 2100 and a display device accommodating case 2200. The head mounting band 2100 may be extended to the display device accommodating case 2200. The head mounting band 2100 may include a horizontal band and/or a vertical band, used to fix the head mounted display device 2000 to the head of the user. The horizontal band may be configured to surround a side portion of the head of the user, and the vertical band may be configured to surround an upper portion of the head of the user. However, embodiments are not limited thereto. For example, the head mounting band 2100 may be implemented in the form of a glasses frame, a helmet, or the like.

The display device accommodating case 2200 may accommodate the first and second display devices 1210 and 1220 shown in FIG. 15. The display device accommodating case 2200 may further accommodate the processor 1100 shown in FIG. 15.

In accordance with the disclosure, there can be provided a display device and a method of manufacturing a display device, which can increase light emission efficiency and reduce a risk that a leakage current may be generated between partition walls.

The above description is an example of technical features of the disclosure, and those skilled in the art to which the disclosure pertains will be able to make various modifications and variations. Thus, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a light emitting portion disposed on a base layer;
a partition wall disposed adjacent to the light emitting portion; and
a partition wall insulating layer covering at least a portion of the partition wall, wherein
the partition wall includes:
a first partition wall layer;
a second partition wall layer disposed on the first partition wall layer; and
a third partition wall layer disposed on the second partition wall layer,
the third partition wall layer includes a Transparent Conductive Oxide (TCO) material, and
the partition wall insulating layer does not cover a top surface of the light emitting portion.

2. The display device of claim 1, wherein the first partition wall layer and the third partition wall layer protrude outwardly of the second partition wall layer in a direction in which a plane on which the base layer is disposed extends.

3. The display device of claim 2, wherein
the second partition wall layer includes a reflective metal material, and
the first partition wall layer includes a TCO material.

4. The display device of claim 3, wherein
the first partition wall layer includes at least one selected from the group consisting of Indium Tin Oxide (ITO), Indium Zinc Oxide (IZO), Indium Gallium Zinc Oxide (IGZO), and Aluminum Zinc Oxide (AZO),
the second partition wall layer includes at least one of silver (Ag) and aluminum (Al), and
the third partition wall layer includes an amorphous TCO material.

5. The display device of claim 3, wherein
the first partition wall layer has a thickness in a range of about 30 Å to about 100 Å,
the second partition wall layer has a thickness in a range of about 4000 Å to about 10000 Å, and
the third partition wall layer has a thickness in a range of about 500 Å to about 2000 Å.

6. The display device of claim 1, wherein the partition wall insulating layer covers a side surface of each of the first partition wall layer, the second partition wall layer, and the third partition wall layer.

7. The display device of claim 1, wherein
the partition wall insulating layer is in contact with at least a portion of a side surface of the light emitting portion, and
the first partition wall layer is in contact with the second partition wall layer, and
the third partition wall layer is in contact with the second partition wall layer.

8. The display device of claim 6, wherein the partition wall insulating layer does not cover a top surface of the third partition wall layer.

9. The display device of claim 8, wherein the partition wall insulating layer includes at least one selected from the group consisting of silica (SiO₂) and aluminum oxide (A₂O₃).

10. The display device of claim 9, wherein the partition wall insulating layer has a thickness in a range of about 100 Å to about 500 Å.

11. The display device of claim 1, further comprising:
a second electrode disposed on the light emitting portion; and
an auxiliary electrode disposed on the second electrode, the auxiliary electrode being electrically connected to the second electrode.

12. The display device of claim 11, wherein the auxiliary electrode includes at least one selected from the group consisting of a TCO material and titanium nitride (TiN).

13. A method of manufacturing a display device, the method comprising:
forming a first electrode on a base layer;
forming a partition wall on the base layer;
forming a partition wall insulating layer on the partition wall;
forming a light emitting portion adjacent to the partition wall;
forming a second electrode on the light emitting portion; and
forming an auxiliary electrode on the second electrode, wherein
the forming of the partition wall on the base layer includes:
depositing a first base partition wall layer;
depositing a second base partition wall layer on the first base partition wall layer; and
depositing a third base partition wall layer on the second base partition wall layer,
the third base partition wall layer includes a Transparent Conductive Oxide (TCO) material, and
the forming of the auxiliary electrode on the second electrode includes disposing the auxiliary electrode directly on the second electrode such that the auxiliary electrode and the second electrode are electrically connected to each other.

14. The method of claim 13, further comprising:
forming a base pixel defining layer to cover the first electrode, wherein
the first base partition wall layer is deposited on the base pixel defining layer, and
the forming of the partition wall on the base layer includes:
forming a first partition wall layer, a second middle partition wall layer, and a third partition wall layer by collectively performing wet etching on the first base partition wall layer, the second base partition wall layer, and the third base partition wall layer; and
forming a second partition wall layer having a structure retracted inwardly of the first partition wall layer and the third partition wall layer by further etching the second middle partition wall layer.

15. The method of claim 14, wherein the third partition wall layer includes at least one selected from the group consisting of Indium Zinc Oxide (IZO) and Indium Gallium Zinc Oxide (IGZO).

16. The method of claim 14, wherein the forming of the partition wall insulating layer on the partition wall includes:
depositing a base partition wall insulating layer to cover a side surface of the partition wall, a top surface of the third partition wall layer, and at least a portion of a top surface of the base pixel defining layer; and
exposing the top surface of the third partition wall layer by performing dry etching on the base partition wall insulating layer.

17. The method of claim 16, further comprising:
forming a pixel defining layer on the partition wall, wherein
the forming of the pixel defining layer includes:
removing at least a portion of the base pixel defining layer; and
exposing, by the pixel defining layer, at least a portion of the first electrode, and
the removing and the forming of the partition wall insulating layer are performed in the same dry etching process.

18. The method of claim 16, wherein
the base partition wall insulating layer includes silica (SiO₂) or aluminum oxide (Al₂O₃),
in case that the base partition wall insulating layer includes silica (SiO₂), the base partition wall insulating layer is deposited through a Chemical Vapor Deposition (CVD) process, and
in case that the base partition wall insulating layer includes aluminum oxide (Al₂O₃), the base partition wall insulating layer is deposited through an Atomic Layer Deposition (ALD) process.

19. The method of claim 13, wherein
the forming of the auxiliary electrode on the second electrode includes depositing the auxiliary electrode through an ALD process, and
the auxiliary electrode includes at least one selected from the group consisting of a TCO material and titanium oxide (TiN).

20. A display device comprising:
a first electrode disposed on a base layer;
a light emitting portion disposed on the first electrode;
a second electrode disposed on the light emitting portion;
a partition wall disposed adjacent to the light emitting portion;
a partition wall insulating layer covering at least a portion of the partition wall; and
an auxiliary electrode covering the second electrode and the partition wall, wherein
the partition wall includes:
a first partition wall layer;
a second partition wall layer disposed on the first partition wall layer; and
a third partition wall layer disposed on the second partition wall layer,
the third partition wall layer includes an amorphous Transparent Conductive Oxide (TCO) material,
the partition wall insulating layer include an inorganic material, and
the second electrode and the auxiliary electrode are electrically connected to each other.
